(19) United States
(12) Patent Application Publication
(10) Pub. No.: US 2008/0017928 A1
(43) Pub. Date: Jan. 24, 2008

(54) Semiconductor Device and Method for Manufacturing the Same

(76) Inventor: JONG TAEK HWANG, Cheongju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/779,992

(22) Filed: Jul. 19, 2007

(30) Foreign Application Priority Data
Jul. 21, 2006 (KR) 10-2006-0068691

(51) Int. Cl. H01L 29/78; H01L 21/469

(52) U.S. Cl. 257/368; 438/763; 257/E29.255; 257/E21.483

(57) ABSTRACT

Disclosed are a semiconductor device and a method for manufacturing the same. The semiconductor device can include at least two gate structures spaced apart from each other on a semiconductor substrate, a silicon nitride layer covering the semiconductor substrate and the gate structures, an interlayer dielectric layer on the silicon nitride layer, and a buffer layer interposed between the silicon nitride layer and the interlayer dielectric layer to buffer stress between the silicon nitride layer and the interlayer dielectric layer. The buffer layer has a tensile stress characteristic, while the silicon nitride layer and the interlayer dielectric layer have a compressive stress characteristic. Therefore, the buffer layer buffers the compressive stress of both the silicon nitride layer and the interlayer dielectric layer. Accordingly, the delamination or the damage of the silicon nitride layer and the interlayer dielectric layer is inhibited.

### CROSS-REFERENCE TO RELATED APPLICATION

The present application claims the benefit under 35 U.S.C. §119 of Korean Patent Application No. 10-2006-0068691, filed Jul. 21, 2006, which is hereby incorporated by reference in its entirety.

### BACKGROUND

Recently, the integration degree of a semiconductor device increases about twice every two years. Accordingly, the chip size and the circuit line width of the semiconductor device have been gradually reduced, causing problems that may not occur in the related semiconductor device.

A pre-metal dielectric (PMD) layer signifies an interlayer dielectric layer for insulating a gate structure from a metal interconnection. The PMD layer has superior gap-fill performance, gathering performance, and a low absorptive property. In addition, the PMD layer must be easily planarized.

The gap-fill performance refers to the property for filling the gap caused by the pattern of the semiconductor device, and the gathering performance refers to capability of trapping mobile ions, such as sodium ions or other metal ions that degrade the characteristics of the semiconductor device.

A silicon oxide layer, which is often used as an insulating layer, is insufficient for filling the gap formed by the gate structure. Accordingly, since a PMD layer including the silicon oxide layer may have a void, a characteristic of the semiconductor device is degraded, and an electrical short occurs between contacts due to the voids. For this reason, the yield rate of the semiconductor device may be lowered.

Accordingly, recently, a borophosphosilicate glass (BPSG) layer, a phosphosilicate glass (PSG) layer or a high density plasma-undoped silicon glass (HDP-USG) layer formed by using high density plasma-chemical vapor deposition (HDP-CVD) equipment is widely used, instead of the silicon oxide layer.

However, when the HDP-USG layer is formed on a silicon nitride layer after forming the silicon nitride layer on the gate structure in order to protect the gate structure, the silicon nitride layer and the HDP-USG layer may be mutually delaminated. The mutual delamination of the silicon nitride layer and the HDP-USG layer may frequently occur when the compressive stress of the HDP-USG layer, which is weak against the compressive stress, overlaps with the compressive stress of the silicon nitride layer, which is also weak against the compressive stress.

When the silicon nitride layer and the HDP-USG layer are delaminated as described above, a metal material connected to the gate structure may penetrate into the delamination space, causing the electrical short between semiconductor devices.

### BRIEF SUMMARY

A semiconductor device according to an embodiment of the present invention includes at least two gate structures spaced apart from each other on a semiconductor substrate, a silicon nitride layer covering the semiconductor substrate and the gate structures, a planarized interlayer dielectric layer covering the silicon nitride layer, and a buffer layer interposed between the silicon nitride layer and the interlayer dielectric layer.

In another aspect of the present invention, a method for manufacturing a semiconductor device according to an embodiment includes forming at least two gate structures spaced apart from each other on a semiconductor substrate, forming a silicon nitride layer on the semiconductor substrate and the gate structures, forming a buffer layer on the silicon nitride layer, and forming an interlayer dielectric layer on the buffer layer.

Other systems, methods, features and advantages will be, or will become, apparent to one with skill in the art upon examination of the following figures and detailed description. Nothing in this section should be taken as a limitation on those claims. Further aspects and advantages are discussed below in conjunction with the embodiments.

### BRIEF DESCRIPTION OF THE DRAWINGS

FIG. 1 is a cross-sectional view of a semiconductor device according to an embodiment of the present invention;

FIGS. 2-5 are cross-sectional views for explaining a method for manufacturing a semiconductor device according to an embodiment of the present invention.

FIG. 2 is a cross-sectional view showing a gate structure formed on a semiconductor substrate according to an embodiment;

FIG. 3 is a cross-sectional view showing a silicon nitride layer formed on the gate structure shown in FIG. 2;

FIG. 4 is a cross-sectional view showing a buffer layer formed on the silicon nitride layer shown in FIG. 3; and

FIG. 5 is a cross-sectional view showing an interlayer dielectric layer formed on the buffer layer shown in FIG. 4.

### DETAILED DESCRIPTION

Hereinafter, a semiconductor device and a method for manufacturing the same according to embodiments of the present invention will be described in detail with respect to accompanying drawings. It will be apparent to those skilled in the art that the present invention is not limited to the following embodiments, and various modifications and variations can be realized within the scope of the appended claims and their equivalents. In the accompanying drawings, sizes of a semiconductor device, a gate structure, a silicon nitride layer, an interlayer dielectric layer, a buffer layer, and other structures are enlarged for ease of understanding. In the description of embodiments, when a layer or structure is described as being formed “on,” “on an upper surface,” “below” or “on a lower surface,” it means that the layer or structure is directly or indirectly formed on the upper surface or below the lower surface of a layer or structure.

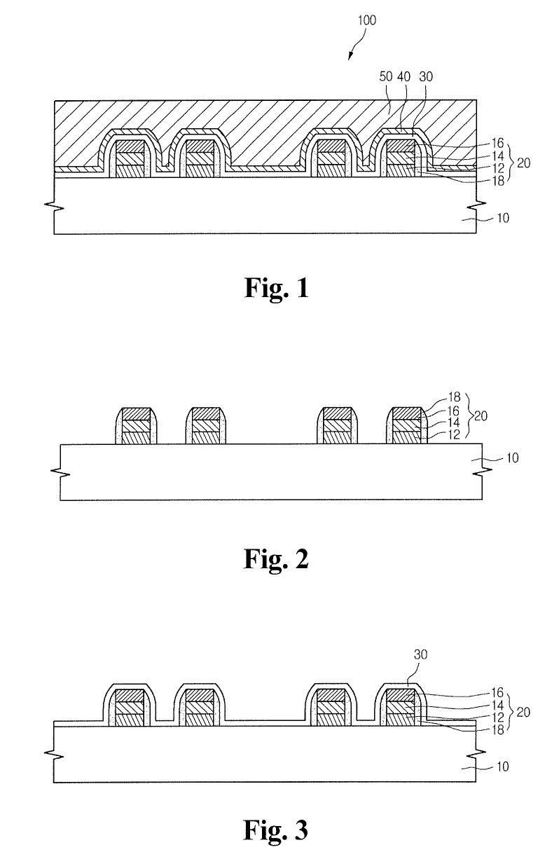

FIG. 1 is a cross-sectional view of a semiconductor device according to an embodiment.

Referring to FIG. 1, a semiconductor device 100 can include a semiconductor substrate 10, a gate structure 20, a silicon nitride layer 30, a buffer layer 40, and an interlayer dielectric (ILD) layer 50.

The gate structure 20 is disposed on the semiconductor substrate 10. In one embodiment, the gate structure 20 includes a gate oxide layer pattern 12, a gate conductive layer pattern 14, a hard mask layer pattern 16, and spacers 18.

The gate oxide layer pattern 12 is disposed on the semiconductor substrate 10, and the gate conductive layer pattern 14 is formed on the gate oxide layer pattern 12. According to an embodiment, the conductive layer pattern 14 includes various metals such as, for example, aluminum (Al), aluminum alloy, tungsten (W), or tungsten alloy.

The hard mask layer pattern 16 is formed on the gate conductive layer pattern 14, and the spacers 18 can be formed at the sides of the gate oxide layer pattern 12, the gate conductive layer pattern 14, and the hard mask layer pattern 16.

According to an embodiment, at least two gate structures 20 are provided as a pair, and the distance between the gate structures 20 can be, for example, in a range of about 1,700 Å to 1,900 Å.

According to the present embodiment, the gate structure 20 includes the gate oxide layer pattern 12, the gate conductive layer pattern 14, the hard mask pattern 16, and the spacers 18. In various embodiments, the gate structure 20 can be used as a floating gate structure of a non-volatile memory, or a split gate structure of a flash memory device. The components of the gate structure can be variously changed. In addition, the gate structure can be variously constructed.

The silicon nitride layer 30 can cover the semiconductor substrate 10 including the gate structure 20. According to an embodiment, the silicon nitride layer 30 can serve as an etching preventing layer, which prevents the gate structure 20 from being etched, and/or a passivation layer, which protects the gate structure 20. According to one embodiment, the silicon nitride layer 30 can have a thickness in the range of about 200 Å to about 300 Å.

The interlayer dielectric layer 50 is formed on the silicon nitride layer 30. The interlayer dielectric layer 50 can be an HDP-USG layer formed through an HDP-CVD process. The interlayer dielectric layer 50 according to the present embodiment includes a pre-metal dielectric (PMD) layer, and is precisely buried between the gate structures 20 even though a step difference exists due to the gate structures 20.

However, when the interlayer dielectric layer 50 having a compressive stress characteristic is directly formed on the top surface of the silicon nitride layer 30 having a compressive stress characteristic, the compressive stress of the silicon nitride layer 30 overlaps with the compressive stress of the interlayer dielectric layer 50, so that the silicon nitride layer 30 and the interlayer dielectric layer 50 may be mutually delaminated or destructed.

Accordingly, in order to inhibit the mutual delamination of the silicon nitride layer 30 and the interlayer dielectric layer 50 having compressive stress characteristics, a buffer layer 40 having tensile stress characteristics is interposed between the silicon nitride layer 30 and the interlayer dielectric layer 50.

The buffer layer 40 having the tensile stress characteristic compensates for (absorbs) the compressive stress generated from the silicon nitride layer 30 and the interlayer dielectric layer 50 to reduce the compressive stress formed between the silicon nitride layer 30 and the interlayer dielectric layer 50, thereby inhibiting the silicon nitride layer 30 and the interlayer dielectric layer 50 from being mutually delaminated.

According to an embodiment, the buffer layer 40 can be an O₃-based undoped silicate glass (O₃-USG) thin film. In detail, the buffer layer 40 can be formed by depositing an O₃-USG material, which is obtained by reacting tetra ethyl ortho silicate (TEOS) gas using ozone (O3) as a catalyst, on the silicon nitride layer 30. According to one embodiment, the thickness of the O₃-USG thin film can be in the range of about 150 Å to about 450 Å.

The buffer layer 40 according to the present embodiment buffers (or absorbs) stress between the silicon nitride layer 30 and the interlayer dielectric layer 50, thereby inhibiting the silicon nitride layer 30 and the interlayer dielectric layer 50 from being mutually delaminated. Accordingly, when the buffer layer 40 is formed between the silicon nitride layer 30 and the gate structure 20, or when the buffer layer 40 is formed on an upper portion of the interlayer dielectric layer 50, the function of the buffer layer 40 cannot be performed. Accordingly, the buffer layer 40 according to the present embodiment is interposed between the silicon nitride layer 30 and the interlayer dielectric layer 50.

According to embodiments, the buffer layer 40 having a tensile stress characteristic is interposed between the silicon nitride layer 30 having a compressive stress characteristic and the interlayer dielectric layer 50 having a compressive stress characteristic, thereby inhibiting the silicon nitride layer 30 and the interlayer dielectric layer 50 from being damaged.

FIGS. 2-5 show cross-sectional views for explaining a method of manufacturing a semiconductor device according to an embodiment of the present invention.

Referring to FIG. 2, in one embodiment, gate stack structures 20 can be formed on a substrate 10. For example, an ion implanting process can be performed to form a well (not shown) on the semiconductor substrate 10. An embodiment method for forming the gate structures 20 is described below.

A gate oxide layer (not shown) is formed on the semiconductor substrate 10. A polysilicon layer is formed to be used as a gate on the gate oxide layer, and a gate conductive layer having conductivity is formed by doping the polysilicon layer with high concentration impurities. A hard mask layer including silicon oxide is formed on the gate conductive layer. In addition, an anti-reflecting layer can be additionally formed on the hard mask layer.

Then a photoresist film is formed on the hard mask layer through a spin coating process, and then etched through a photolithography process, thereby forming a photoresist pattern on the hard mask layer. After the photoresist pattern is formed on the hard mask layer, the hard mask layer is etched using the photoresist pattern as an etching mask, thereby forming a hard mask pattern 16. Subsequently, the photoresist pattern formed on the hard mask pattern 16 is removed from the hard mask pattern 16 through an ashing process using oxygen plasma.

After the hard mask pattern 16 is formed, the polysilicon layer and the gate oxide layer are sequentially etched using the hard mask pattern 16 as an etching mask, thereby forming the gate conductive layer pattern 14 and the gate oxide layer pattern 12 on the semiconductor substrate 10.

Subsequently, a silicon nitride layer (or an oxide layer) is formed on the semiconductor substrate 10 covering the top surface and the sidewalls of the hard mask pattern 16, the sidewalls of the gate conductive layer pattern 14, and the sidewalls of the gate oxide layer pattern 12. Then, the silicon nitride layer is etched through an etch back process, thereby forming spacers 18 at the sidewalls of the hard mask pattern 16, the sidewalls of the gate conductive layer pattern 14, and the sidewalls of the gate oxide layer pattern 12.

According to an embodiment, at least two gate structures 20 are disposed on the semiconductor substrate 10 while being spaced apart from each other by a distance in the range of about 1,700 Å to about 1,900 Å.

Referring to FIG. 3, after the gate structure 20 is formed, a silicon nitride layer 30 can be formed to cover the semiconductor substrate 10 and the gate structure 20. According to an embodiment, the silicon nitride layer 30 may have a thickness in the range of 200 Å to 300 Å. The silicon nitride layer 30 can serve as a passivation layer to protect the gate structure 20 or an etching preventing layer to prevent the gate structure 20 from being etched. The silicon nitride layer 30 can have a compressive stress characteristic.

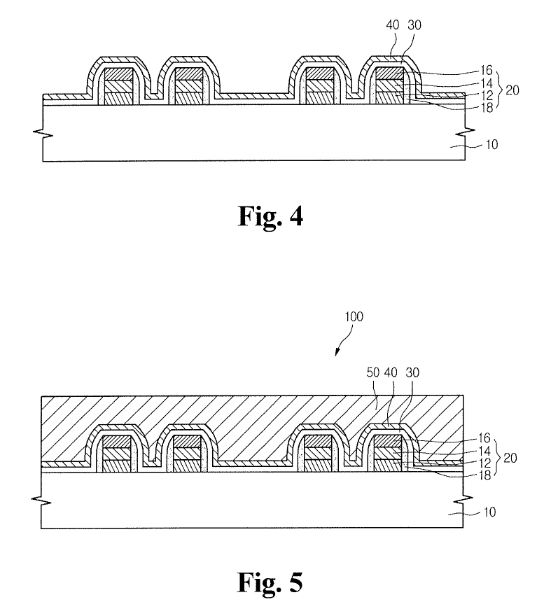

Referring to FIG. 4, after the silicon nitride layer 30 is formed, a buffer layer 40 is formed on the top surface of the silicon nitride layer 30. According to an embodiment, the thickness of the buffer layer 40 is in the range of about 150 Å to about 450 Å. The buffer layer 40 can be formed through a thermal chemical vapor deposition process.

According to one embodiment, the buffer layer 40 can be formed by depositing an O₃-USG material, which is obtained by reacting tetra ethyl ortho silicate (TEOS) gas using ozone (O₃) as a catalyst, on the silicon nitride layer 30. Since the buffer layer 40 has a tensile stress characteristic, the buffer layer 40 can offset (or absorb) the compressive stress of the silicon nitride layer 30.

Referring to FIG. 5, after the buffer layer 40 having the tensile stress characteristic is formed on the semiconductor substrate 10, an interlayer dielectric layer 50 such as an HDP-USG layer can be formed on the buffer layer 40 in order to fill the gap formed between the gate structures 20 without voids. According to an embodiment, the interlayer dielectric layer 50 can be formed through an HDP-CVD process. Although the interlayer dielectric layer 50 formed on the buffer layer 40 has a compressive stress characteristic, since the buffer layer 40 provided below the interlayer dielectric layer 50 has a tensile stress characteristic, the compressive stress of the interlayer dielectric layer 50 is greatly buffered.

According to the present embodiment, the buffer layer 40 interposed between the interlayer dielectric layer 50 and the silicon nitride layer 30 has a tensile stress characteristic. Therefore, the compressive stress of both the interlayer dielectric layer 50 and the silicon nitride 30 is offset by the buffer layer 40, thereby inhibiting the interlayer dielectric layer 50 and the silicon nitride 30 from being mutually delaminated.

As described above, the buffer layer having a tensile stress characteristic is disposed between two thin films (i.e., the silicon nitride layer covering the gate structure and the interlayer dielectric layer provided on the silicon nitride layer) having a compressive stress characteristic, thereby buffering the compressive stress of both the silicon nitride layer and the interlayer dielectric layer. Accordingly, the delamination or the damage of the silicon nitride layer and the interlayer dielectric layer can be inhibited.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive. The above disclosed subject matter is to be considered illustrative, and not restrictive, and the appended claims are intended to cover all such modifications, enhancements, and other embodiments, which fall within the true spirit and scope of the present invention.

What is claimed is:

1. A semiconductor device comprising:
at least two gate structures spaced apart from each other on a semiconductor substrate;
a silicon nitride layer on the semiconductor substrate including the at least two gate structures;
an interlayer dielectric layer on the silicon nitride layer; and
a buffer layer to inhibit delamination interposed between the silicon nitride layer and the interlayer dielectric layer.

2. The semiconductor device according to claim 1, wherein the buffer layer comprises an O₃-based undoped silicate glass (O₃-USG) layer.

3. The semiconductor device according to claim 2, wherein the O₃-based undoped silicate glass (O₃-USG) layer has a thickness in a range of about 150 Å to 450 Å.

4. The semiconductor device according to claim 1, wherein a distance between two gate structures of the at least two gate structures is in a range of 1,700 Å to 1,900 Å.

5. The semiconductor device according to claim 1, wherein the interlayer dielectric layer comprises a high density plasma-undoped silicon glass (HDP-USG) layer.

6. The semiconductor device according to claim 1, wherein the silicon nitride layer and the interlayer dielectric layer have compressive stress characteristics, and the buffer layer has a tensile stress characteristic that compensates for the compressive stress characteristics.

7. A method for manufacturing a semiconductor device comprising:
forming at least two gate structures on a semiconductor substrate;
forming a silicon nitride layer on the semiconductor substrate including the at least two gate structures;
forming a delamination inhibiting buffer layer on the silicon nitride layer; and
forming an interlayer dielectric layer on the buffer layer.

8. The method according to claim 7, wherein, forming the delamination inhibiting buffer layer comprises depositing an O₃-based undoped silicate glass (O₃-USG) layer, which is obtained by reacting tetra ethyl ortho silicate (TEOS) gas using ozone (O₃) a catalyst.

9. The method according to claim 8, wherein depositing the O₃-USG layer comprises performing a thermal chemical vapor deposition (thermal CVD) process.

10. The method according to claim 7, wherein forming the interlayer dielectric layer comprises performing a high density plasma-chemical vapor deposition (HDP-CVD) process.

11. The method according to claim 10, wherein the interlayer dielectric layer comprises a high density plasma-undoped silicon glass (HDP-USG) layer.

12. The method according to claim 7, wherein the delamination inhibiting buffer layer has a tensile stress to compensate for the compressive stress of the silicon nitride layer and the compressive stress of interlayer dielectric layer, thereby inhibiting delamination of both the silicon nitride layer and the interlayer dielectric layer.
